(19) United States
(12) Patent Application Publication
(10) Pub. No.: US 2017/0268711 A1
(43) Pub. Date: Sep. 21, 2017

(54) BRANCHING STRUCTURE

(71) Applicant: Kabushiki Kaisha Toshiba, Minato-ku (JP)

(72) Inventors: Masayuki TANAKA, Yokohama (JP); Takahiro TERADA, Yokohama (JP); Shiguma KATO, Yokohama (JP); Shinji NAKATA, Yokohama (JP)

(73) Assignee: Kabushiki Kaisha Toshiba, Minato-ku (JP)

(21) Appl. No.: 15/424,098

(22) Filed: Feb. 3, 2017

(30) Foreign Application Priority Data
Mar. 15, 2016 (JP) 2016-051095

(51) Int. Cl. F16L 41/03; B05B 1/18; C23C 16/455; F16L 55/027

(52) U.S. Cl. CPC F16L 41/03; F16L 55/027; B05B 1/18; C23C 16/45565

(57) ABSTRACT

A branching structure according to an embodiment includes an introduction path part and branch path parts. The introduction path part includes an introduction path extending in a first direction. The branch path part includes parallel branch paths. The branch paths each include an upstream section extending in a second direction intersecting with the first direction and a downstream section extending in the first direction. The branch paths continue into the introduction path or upstream branch paths. In each of the branch path parts, the numbers of the upstream sections up to the branch paths are the same. The branch path parts more downstream have a larger number of downstream sections.

### CROSS-REFERENCE TO RELATED APPLICATIONS

This application is based upon and claims the benefit of priority from Japanese Patent Application No. 2016-051095, filed Mar. 15, 2016, the entire contents of which are incorporated herein by reference.

### FIELD

Embodiments described herein relate generally to a branching structure.

### BACKGROUND

Conventionally, shower heads supply a gas through multiple outlets are known.

It is useful to attain a branching structure that can reduce variation in a flow rate of the gas supplied through the outlets, for example.

### BRIEF DESCRIPTION OF THE DRAWINGS

FIG. 1 is a schematic and exemplary sectional view of a processing device according to an embodiment described herein;

FIG. 2 is a schematic and exemplary view illustrating an end face and outlets of a branching structure in the embodiment;

FIG. 3 is a schematic and exemplary plan view illustrating tiling of the outlets in the end face of the branching structure in the embodiment;

FIG. 4 is a schematic and exemplary plan view of a different example from FIG. 3, illustrating the tiling of the outlets in the end face of the branching structure in the embodiment;

FIG. 5 is a schematic and exemplary plan view of a different example from FIGS. 3 and 4, illustrating the tiling of the outlets in the end face of the branching structure in the embodiment;

FIG. 6 is a schematic and exemplary view of a cross section of the branching structure in the embodiment;

FIG. 7 is a schematic and exemplary plan view of an end face and outlets of a branching structure according to a first embodiment;

FIG. 8 is a schematic and exemplary plan view, from an inlet side, of a virtual stereoscopic image of a path provided in the branching structure in the first embodiment;

FIG. 9 is a schematic and exemplary perspective view of the virtual stereoscopic image of the path provided in the branching structure in the first embodiment;

FIG. 10 is a schematic and exemplary plan view of an end face and outlets of a branching structure according to a second embodiment;

FIG. 11 is a schematic and exemplary plan view, from an inlet side, of a virtual stereoscopic image of a path provided in the branching structure in the second embodiment;

FIG. 12 is a schematic and exemplary perspective view of the virtual stereoscopic image of the path provided in the branching structure in the second embodiment;

FIG. 13 is a schematic and exemplary plan view, from an inlet side, of a virtual stereoscopic image of a path provided in a branching structure according to a first modification;

FIG. 14 is a schematic and exemplary perspective view of the virtual stereoscopic image of the path provided in the branching structure in the first modification;

FIG. 15 is a schematic and exemplary plan view of an end face and outlets of a branching structure according to a third embodiment;

FIG. 16 is a schematic and exemplary plan view, from an inlet side, of a virtual stereoscopic image of a path provided in the branching structure in the third embodiment;

FIG. 17 is a schematic and exemplary perspective view of the virtual stereoscopic image of the path provided in the branching structure in the third embodiment;

FIG. 18 is a schematic and exemplary plan view, from an inlet side, of a virtual stereoscopic image of a path provided in a branching structure according to a second modification;

FIG. 19 is a schematic and exemplary perspective view of the virtual stereoscopic image of the path provided in the branching structure in the second modification;

FIG. 20 is a schematic and exemplary plan view of an end face and outlets of a branching structure according to a fourth embodiment;

FIG. 21 is a schematic and exemplary plan view, from an inlet side, of a virtual stereoscopic image of a path provided in the branching structure in the fourth embodiment;

FIG. 22 is a schematic and exemplary perspective view of the virtual stereoscopic image of the path provided in the branching structure in the fourth embodiment;

FIG. 23 is a schematic and exemplary plan view, from an inlet side, of a virtual stereoscopic image of a path provided in a branching structure according to a third modification;

FIG. 24 is a schematic and exemplary perspective view of the virtual stereoscopic image of the path provided in the branching structure in the third modification;

FIG. 25 is a schematic and exemplary perspective view of a cross section of a branching structure according to a fifth embodiment; and

FIG. 26 is a schematic and exemplary view illustrating an end face and outlets of a branching structure according to a fourth modification.

### DETAILED DESCRIPTION

In general, according to one embodiment, a branching structure includes an introduction path part and branch path parts. The introduction path part includes an introduction path extending in a first direction. The branch path part includes parallel branch paths. The branch paths each includes an upstream section extending in a second direction intersecting with the first direction and a downstream section extending in the first direction. The branch paths continue into the introduction path or upstream branch paths. In each of the branch path parts, the numbers of the upstream sections up to the branch paths are the same. The branch path parts more downstream have a larger number of downstream sections.

Hereinafter, exemplary embodiments of a branching structure will be disclosed. Configurations and control (technical features) in the embodiments described below and functions and results (effects) brought by the configurations and control are merely examples. In the drawings, an X direction, a Y direction, and a Z direction are defined for the sake of simple understanding. The X direction, the Y direction, and the Z direction are perpendicular to one another.

### First Embodiment

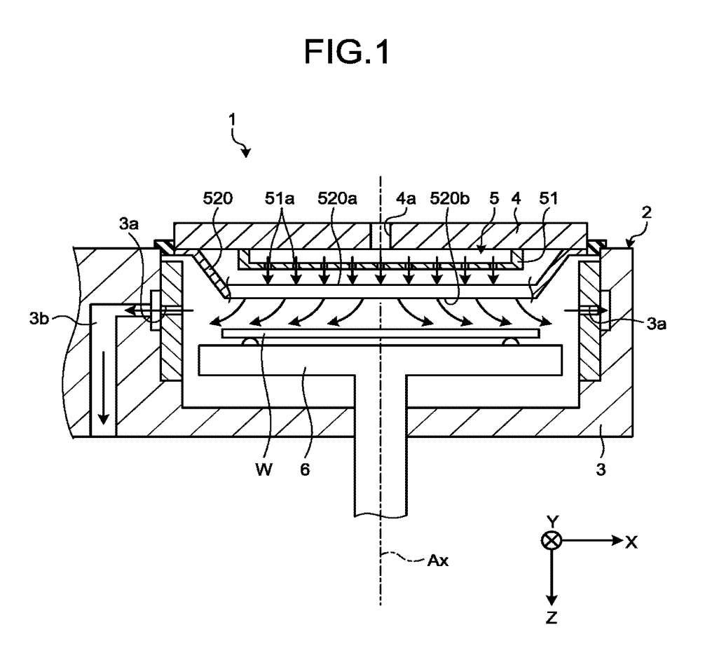

FIG. 1 is a sectional view of a semiconductor processing device 1. The semiconductor processing device 1 applies predetermined processing to a wafer W in an approximately cylindrical chamber (processing vessel) including a base 3 and a lid 4. The semiconductor processing device 1 is, for example, a chemical vapor deposition (CVD) device, and forms a silicon oxide film on the wafer W as an insulating film such as an interlayer insulating film. The base 3 and the lid 4 may also be referred to as walls. The semiconductor processing device 1 is an example of a processing device. The chamber 2 is an example of a processing unit.

The lid 4 is provided with a shower mechanism 5 that supplies a gas onto the wafer W. The shower mechanism 5 includes plates 51 and 520 spaced apart from each other. The plate 51 is provided with through holes 51a through which the gas passes. The plate 522 includes a path (not illustrated) for the gas, the path penetrating through the thickness (along a central axis Ax of FIG. 1) of the plate 520 between both side faces 520a and 520b. The specification including positions, numbers, and sues of the through holes 51a and the path is set to reduce variation in a supply amount of the gas depending on a location on the wafer W as much as possible, for example.

In the chamber 2, the wafer W is supported by a disk-shaped stage 6. The stage 6 can rotatably support the wafer W around the central axis Ax along the thickness of the wafer W. Further, the stage 6 can include a heater, not illustrated, that heats the wafer W.

The lid 4 is provided with a supply vent 4a. The gas is introduced into the shower mechanism 5 and the chamber through the supply vent 4a. The base is provided with an exhaust 3a and an exhaust passage 3b. The gas is discharged from the chamber 2 through the exhaust 3a and the exhaust passage 3b.

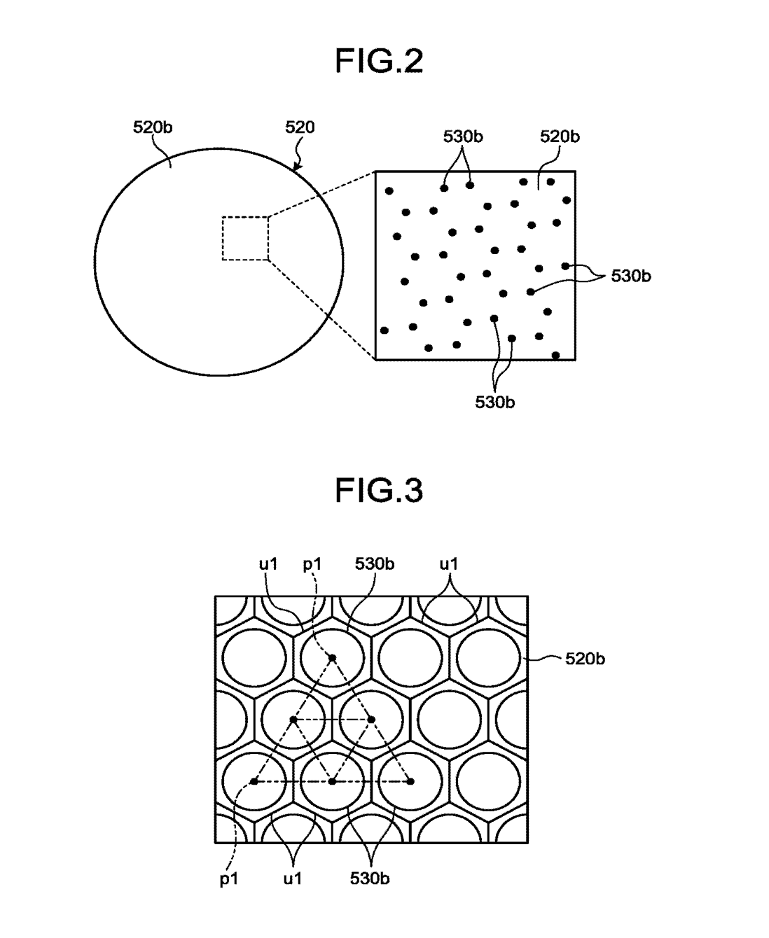

FIG. 2 is a plan view of the face 520b of the plate 520 with outlets 530b and an enlarged view of the outlets 530b. As illustrated in FIG. 2, a number of outlets 530b are regularly arranged to reduce the variation in the supply amount of the gas depending on a location on the face 520b. The plate 520 can be produced with a three-dimensional shaping device, for example, by an arbitrary manufacturing method. The material of the plate 520 is not especially limited. The plate 520 is an example of a branching structure. The plate 520 may also be referred to as a fluid passage device. The face 520b is an example of an end face.

In the present embodiment, layouts (arrangement patterns 1 to 3) of the outlets 530b are determined on the basis of the tiling of polygons as unit shape on a plane.

That is, the outlets 530b are allocated onto the respective fitted polygons of unit shape and can be thereby approximately uniformly distributed on a plane.

### Arrangement Pattern 1 of Outlets

FIG. 3 is an explanatory diagram illustrating the arrangement of the outlets 530b Lased on the tiling of regular hexagons u1 as unit shape. As illustrated in FIG. 3, the outlets 530b are arranged one by one in the respective regular hexagons u1 fitted in the planar face 520b. The outlets 530b have a circular shape and are arranged with their centers and geometric centers of gravity of the regular hexagons u1 overlapping or coinciding with each other. It will be understood from FIG. 3 that the outlets 530b are arranged on the vertexes p1 of equilateral triangles fitted in the face 520b, such that the area of each outlet contains one vertex p1.

Arrangement Pattern 2 of Outlets

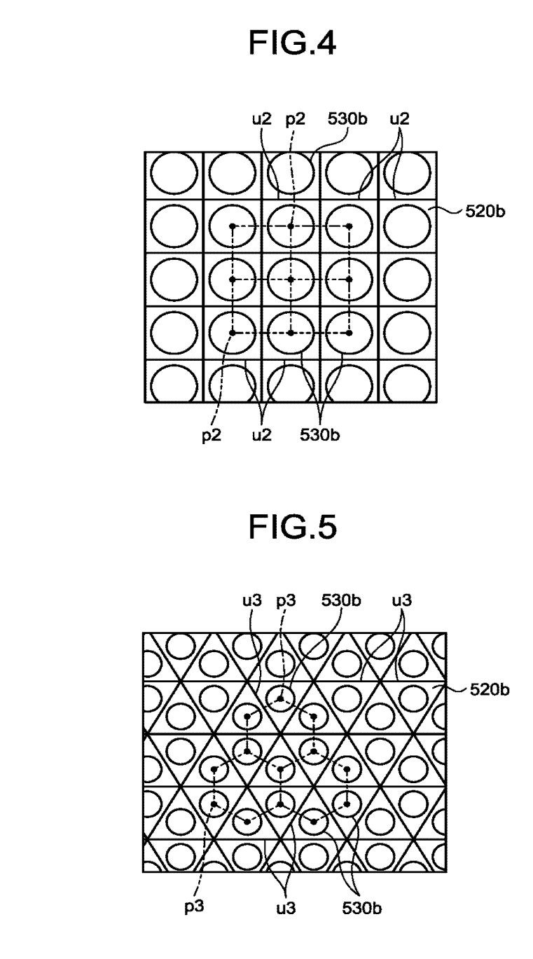

FIG. 4 is an explanatory diagram illustrating the arrangement of the outlets 530b based on the tiling of squares u2 as unit shape. As illustrated in FIG. 4, the outlets 530b are arranged one by one in the respective squares u2 fitted in the planar face 520b. The outlets 530b have a circular shape and are arranged with their centers and geometric centers of gravity of the squares u2 overlapping or coinciding with each other. It will be understood from FIG. 4 that the outlets 530b are arranged on the vertexes p2 of the squares fitted in the face 520b, such that the area of each outlet contains one vertex p2.

Arrangement Pattern 3 of Outlet

FIG. 5 is an explanatory diagram illustrating arrangement of the outlets 530b based on the tiling of equilateral triangles u3 as unit shape. As illustrated in FIG. 5, the outlets 530b are arranged one by one in the respective equilateral triangles u3 fitted in the planar face 520b. The outlets 530b have a circular shape and are arranged with their centers and geometric centers of gravity of the equilateral triangles u3 overlapping or coinciding with each other. It will be understood from FIG. 5 that the outlets 530b are arranged on the vertexes p3 of the regular hexagons fitted in the face 520b, such that the area of each outlet contains one vertex p3.

The plate 520 as a branching structure includes a path for the gas between an inlet and the outlets 530b for discharging the gas (fluid) at the same flow rate through the outlets 5301d arranged in the arrangement patterns 1 to 3. The path diverges at one or more diverging points. The path is configured to uniformly distribute the gas at the diverging points.

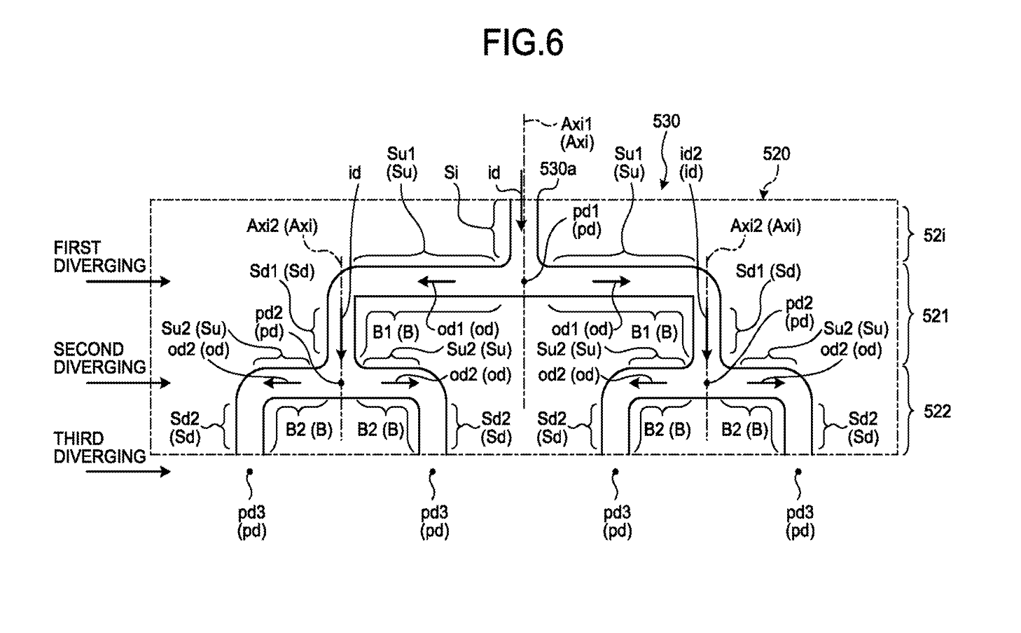

FIG. 6 is a schematic view of an example of a part of a path 530. As illustrated in FIG. 6, in the present embodiment, a straight part of the path 530 up to a first diverging point pd1 is referred to as introduction path Si. The introduction path Si extends in a first direction id. The introduction path Si may not start from an inlet 530a. A part including the introduction path Si is referred to as introduction path part 52i.

A path from a diverging point pd to the next diverging point pd is referred to as branch B. A part of the plate 520 including parallel branches B is referred to as branch path parts 521 and 522. The branch B is an example of a branch path.

The branch B includes upstream sections Su and downstream sections Sd. Bent sections (curved parts) are provided between the upstream sections Su and the downstream sections Sd. Note that the numbers of the upstream sections Su of the branches B1 and B2 are the same in each of the branch path parts 521 and 522. In the example of FIG. 6, the number of the upstream sections Su of all of the branches B1 in the branch path part 521 is “0”. The number of the upstream sections Su of all of the branches B2 in the branch path part 522 is “1”.

In the present embodiment, the path is configured to satisfy the following conditions 1 to 4 so that channel resistance (pressure losses) from the inlet 530a to the outlets 530b (not illustrated in FIG. 6) become approximately constant.

Condition 1: Parallel downstream sections and intersecting upstream sections and downstream sections

The introduction path Si and all of the downstream sections Sd linearly extend in the first direction id in parallel to one another. The upstream sections Su extend in a second direction od intersecting with the first direction id. The smaller the angle difference between the first direction id and the second direction od is, the more easily the gas (fluid) flows from the introduction path Si or downstream section Sd immediately before the diverging point pd to the following upstream section in the next branch B). Because of this, at the diverging points pd, a larger difference in the flow rate is likely to occur due to an error in the angles, positions, or section areas of the upstream sections Su with respect to the introduction path Si or the downstream sections Sd. That is, with a small difference in the angles between the downstream sections Sd and the upstream sections Su, it may be difficult to uniformly distribute the gas. In view of this, as an example, the upstream sections Su and the downstream sections Sd are disposed such that at the diverging points pd, the first direction id and the second direction od are approximately perpendicular to each other.

Condition 2: Branches of Same Shape

All of the branches B have approximately the same shape in each of the branch path parts 521 and 522. In the example of FIG. 6, all of the branches B1 in the branch path part 521 have approximately the same shape, and all of the branches B2 in the branch path part 522 have approximately the same shape. Note that the shape includes, for example, a length, a cross section, or a curvature of the branches B.

Condition 3: Same number of divergences

The numbers of the diverging branches B at the diverging points pd, that is, the numbers of divergences are the same in each of the branch path parts 521 and 522. In the example of FIG. 6, in the branch path part 522, the preceding downstream section Sd1 diverges into two branches B2 at each of the two diverging points pd2. That is, in the branch path part 522, the numbers of the branches B or the numbers of divergences at the two diverging points pd2 are both two.

Condition 4: Rotational symmetry

In each of the branch path parts 521 and 522, the branches B diverge at the diverging points pd to be rotationally symmetric around axes Axi that pass through the diverging points pd in the first direction id in which the preceding downstream section Sd extends. Considering the condition 2, in each of the branch path parts 521 and 522, the numbers of the rotational symmetries at the diverging points pd (=the numbers of divergences, two in the example of FIG. 6) are also the same. In other words, with respect to the condition 3, the branches B connecting to the diverging points pd are provided at fixed angular intervals around the axes Axi, when viewed from the first direction id (along the axes Axi). In the branch path part 522, the two branches B2 connecting to the diverging point pd2 are provided at intervals of 180° in the example of FIG. 6.

The cross section shape of the entire path 530 is circular. However, it should not be limited to the circular shape, and may be an elliptical shape, a polygonal shape, or a long hole shape, for instance.

The inventors have diligently studied to find that limited configurations of the path 530 can satisfy all of the conditions 1 to 4 and any of the arrangement patterns 1 to 3 of the outlets 530b concurrently. The following embodiments and modifications will describe the configurations of the path 530 found by the inventors.

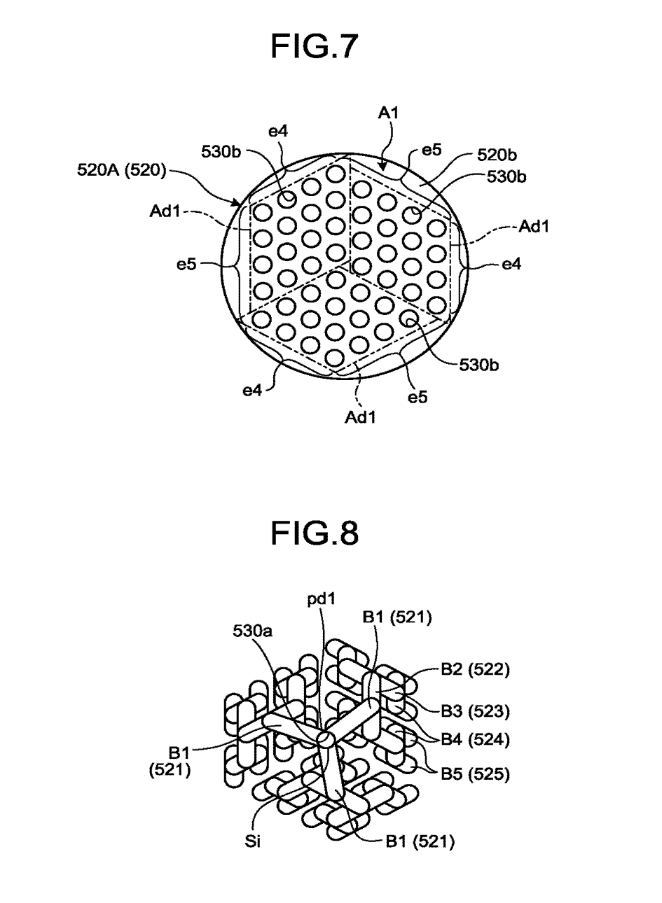

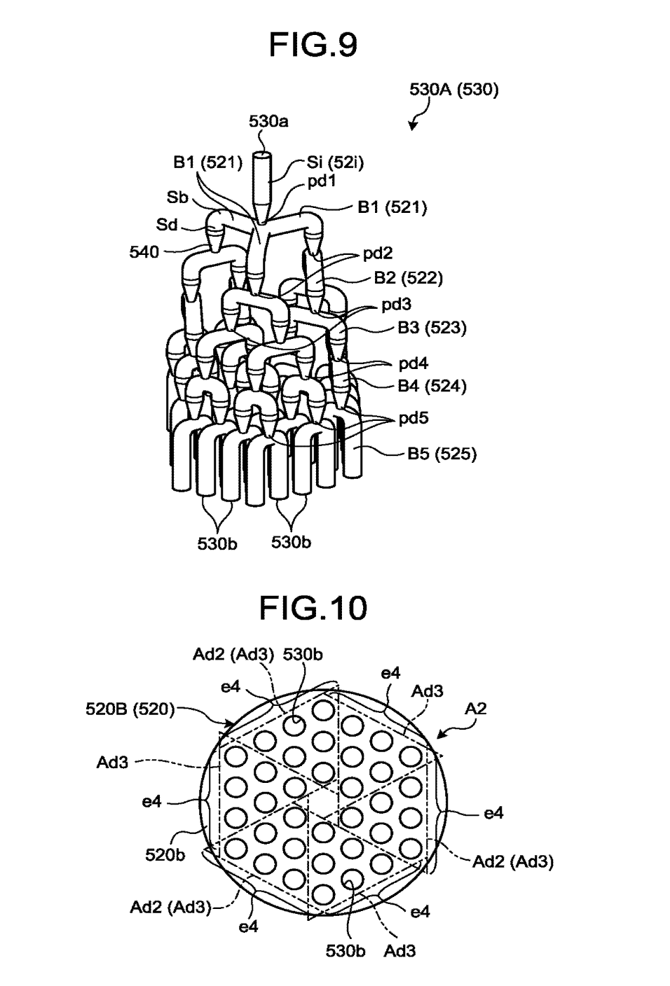

FIG. 7 is a plan view of the discharge-side face 520b of a part of a plate 520A (520) as a branching structure of the first embodiment and the outlets 530b provided in the face 520b. FIG. 8 is a plan view of a virtual stereoscopic image of a path 530A (530) provided in the plate 520A of the first embodiment, and FIG. 9 is a perspective view of the virtual stereoscopic image. FIGS. 8 and 9 stereoscopically illustrate the inner face of the path 530A as a thin tube. The path 530A does not necessarily have a tubular form, and the configuration of the plate 520A is not especially limited.

As illustrated in FIG. 7, in the present embodiment, the outlets 530b are arranged on the face 520b on the basis of the tiling of regular hexagons as unit shape. That is, the outlets 530b are arranged on the vertexes of the fitted equilateral triangles, respectively. The example of FIG. 7 corresponds to the arrangement pattern 1 of the outlets 530b. The face 520b is an example of an end face, and the outlets 530b are an example of termination.

Further, as illustrated in FIG. 7, in the face 520b of the plate 520A, a total of forty-eight outlets 530b are arranged at the outer periphery of a hexagonal area A1 having sides e5 and sides e4 alternately, the sides e5 along each of which five outlets 530b are aligned and the sides e4 along each of which four cutlets 530b are aligned. The area A1 is divided into three areas Ad1 in each of which sixteen outlets 530b are arranged in a diamond form, as illustrated in FIG. 7.

In the path 530A, as illustrated in FIGS. 8 and 9, the introduction path Si diverges into three branches B1 at the first diverging point pd1 so as to satisfy the conditions 1 to 4, and each of the branches B1 is connected to the sixteen cutlets 530b in each area Ad1. Each of the three branches B1 diverges into two branches B2 to B5 at the second to fifth diverging points pd2 to pd5 in the branch path parts 522 to 525 so as to satisfy the conditions 1 to 4. The numbers of divergences at the second to fifth diverging points pd2 to pd5 are all two. That is, in the present embodiment, each of the three split branches B1 at the first diverging point pd1 diverges into 2⁴ (=16) branches B5, and the outlets 530b are provided at the downstream ends of the total of forty-eight branches B5. The parts forming the branches B1 to B5, of the plate 520A, are branch path parts 521 to 525, respectively.

As illustrated in FIG. 9, the branches B1 to B5 each include, in the downstream section Sd, a throttle 540 whose cross section area gradually decreases toward a downstream end. The throttles 540 can work to suppress variation in the flow speed in the cross sections of the downstream sections Sd, and thus the gas (fluid) can more uniformly diverge at the diverging points pd. The throttles 540 are provided further downstream than bent parts Sb between the upstream sections Su and the downstream sections Sd, for example. The throttles 540 may be orifices or chokes.

As described above, in the present embodiment, at the diverging points pd, the first extending direction id (first direction) of the preceding upstream section Su and the second extending direction od of the following downstream section Sd intersect with each other. This makes it possible to more uniformly distribute the gas (fluid) at each diverging point pd from one upstream section Su to the downstream sections Sd.

Further, in the present embodiment, at all of the diverging points pd of the path 530A, the conditions 1 to 4 are satisfied, and the outlets 530b terminating the path 530A are uniformly arranged in the face 520b (end face) of the plate 520A (a branching structure or a fluid passage device) on the basis of the tiling of the regular hexagons (regular polygons) u1 as unit shape. This can reduce variation in the discharge amount of the gas depending on a location on the face 520b (end face).

### Second Embodiment

A second embodiment has the same or like configuration as the first embodiment. Thus, the second embodiment can attain the same or like functions and results (effects) by the same or like configuration.

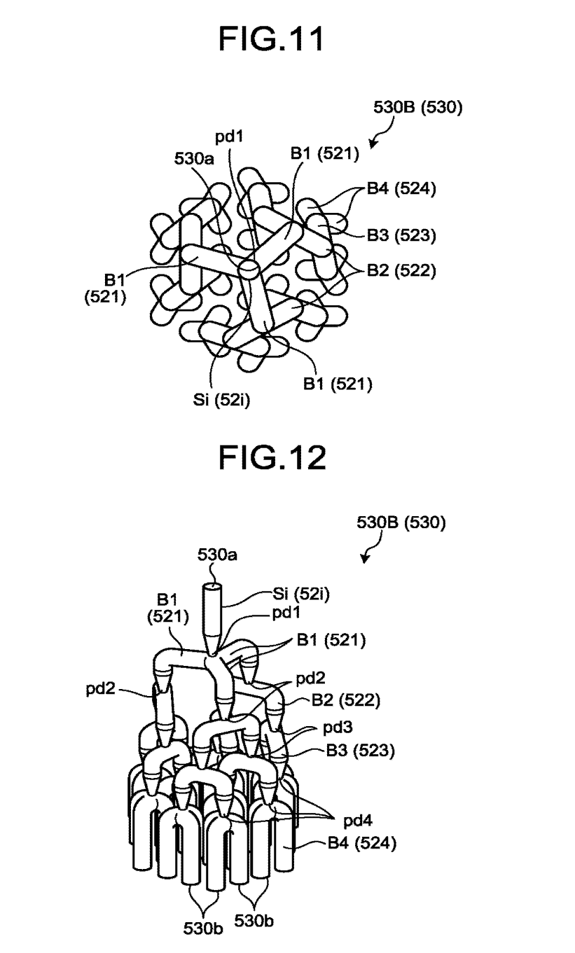

FIG. 10 is a plan view of a discharge-side face 520b of a part of a plate 520E (520) as a branching structure of the second embodiment, and outlets 530b provided on the face 520b. FIG. 11 is a plan view of a virtual stereoscopic image of a path 530E (530) provided in the plate 520E of the second embodiment, and FIG. 12 is a perspective view of the virtual stereoscopic image. FIGS. 11 and 12 stereoscopically illustrate the inner face of the path 530B as a thin tube. In reality, however, the path 530B does not have a tubular form, and the configuration of the plate 520B is not especially limited.

In the present embodiment, the outlets 530b are arranged in the face 520b on the basis of the tiling of regular hexagons as unit shape. That is, the outlets 530b are arranged on the vertexes of fitted equilateral triangles, respectively. The example of FIG. 10 corresponds to the arrangement pattern 1 of the outlets 530b.

As illustrated in FIG. 10, in the face 520b of the plate 520B, a total of thirty-six outlets 530b are arranged at the outer periphery of a hexagonal area A2 having sides e4 along each of which four cutlets 530b are aligned. As illustrated in FIG. 10, the area A2 is divided into three areas Ad2 in each of which twelve outlets 53Db are arranged in a parallelogram form. As is clear from FIG. 10, no outlets 530b are provided in the center of the area A2.

In view of this, as illustrated in FIGS. 11 and 12, in the path 530B, an introduction path Si diverges into three branches B1 at the first diverging point pd1 so as to satisfy the conditions 1 to 4, and one of the branches B1 is connected to twelve outlets 530b in each area Ad2. Then, each of the three branches B1 diverges into two branches B2 and B3 at the second and third diverging points pd2 and pd3 so as to satisfy the conditions 1 to 4 (the numbers of divergences=2). Further, at the fourth diverging points pd4, each of the branches B3 diverges into three branches B4 so as to satisfy the condition 1 to 4 (the number of divergences=3). That is, in the present embodiment, each of the three split branches B1 at the first diverging point pd1 diverges into 2²×3(=12) branches B4, and the outlets 530b are provided at the respective downstream ends of the total of thirty-six branches B4. The parts forming the branches B1 to B4, of the plate 520B, are branch path part 521 to 524, respectively.

### First Modification

A first modification has the same or like configuration as the above embodiments. Thus, the first modification can attain the same or like functions and results (effects) by the same or like configuration.

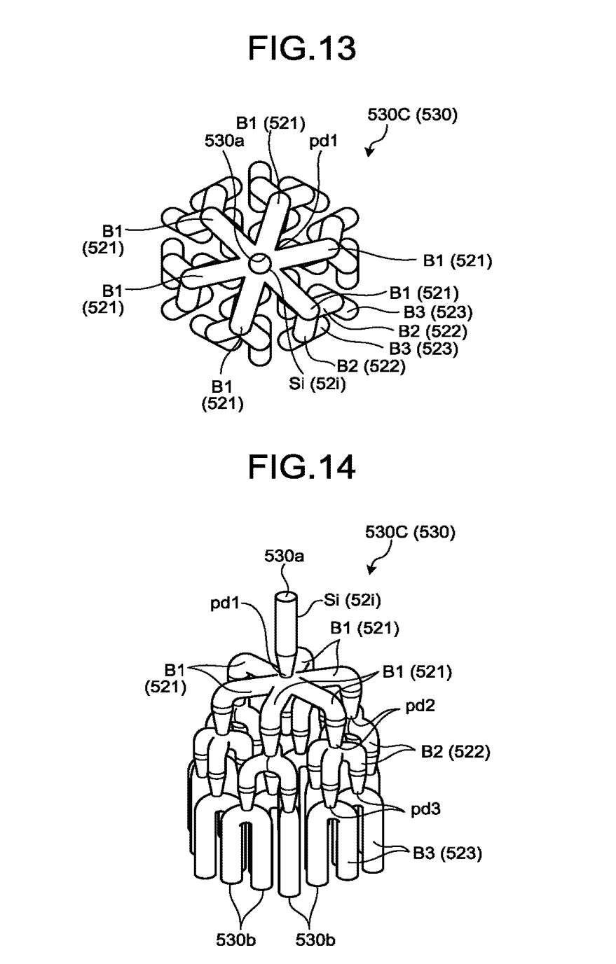

The present modification exemplifies another path 530C in a plate with outlets 530b, which are the same outlets as those of the plate 520B of the second embodiment illustrated in FIG. 10. FIG. 13 is a plan view of a virtual stereoscopic image of the path 530C (530) provided in the plate of the present modification, and FIG. 14 is a perspective view of the virtual stereoscopic image. FIGS. 13 and 14 stereoscopically show the inner face of the path 530C as a thin tube. In reality, however, the path 530C does not have a tubular form, and the configuration of the plate 520B is not especially limited.

As illustrated in FIG. 10, the area A2 is divided into six areas Ad3 in each of which six outlets 530b are arranged in an equilateral triangular form. In view of this, as illustrated in FIGS. 13 and 14, in the path 530C, an introduction path Si diverges into six branches B1 at the first diverging point pd1 so as to satisfy the conditions 1 to 4, and each of the branches B1 is connected to nine outlets 530b in each area Ad3. Then, each of the six branches B1 diverges into three branches B2 at the second diverging point pd2 so as to satisfy the conditions 1 to 4 (the number of divergences=3), and each of the three branches B2 diverges into two branches B3 at the third diverging points pd3 so as to satisfy the conditions 1 to 4 (the number of divergences=2. That is, in the present embodiment, each of the six split branches B1 at the first diverging point pd1 diverges into 3×2(=6) branches B3, and the outlets 530b are provided at the respective downstream ends of the total of thirty-six branches B3. The parts forming the branches B1 to B3, of the plate 520B, are branch path parts 521 to 523, respectively. Note that, if each branch B1 diverges into two branches B2 at the second diverging point pd2 (the number of divergences=2), and each of the branches B2 diverges into three branches B3 at the third diverging point pd3 (the number of divergences=3), the conditions 2 to 4 cannot be satisfied.

### Third Embodiment

A third embodiment has the same or like configuration as the above embodiments. Thus, the third embodiment can attain the same or like functions and results (effects) by the same or like configuration.

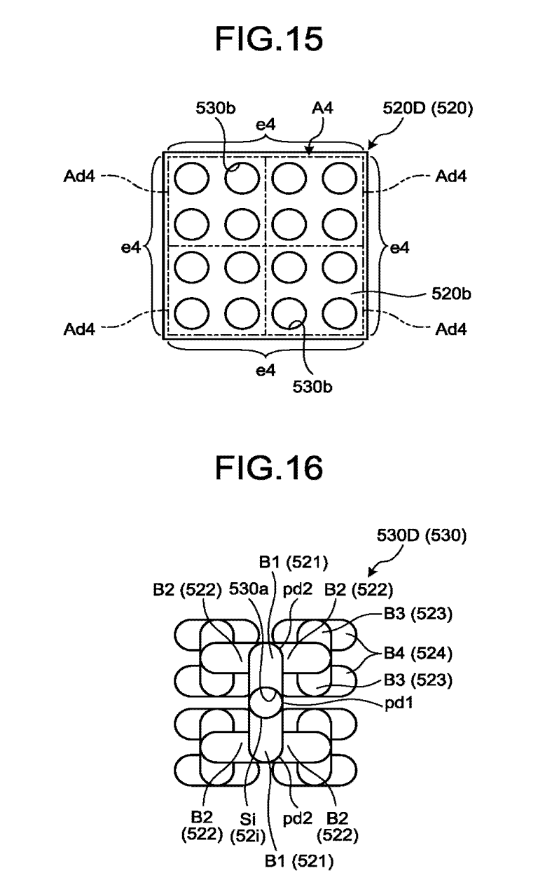

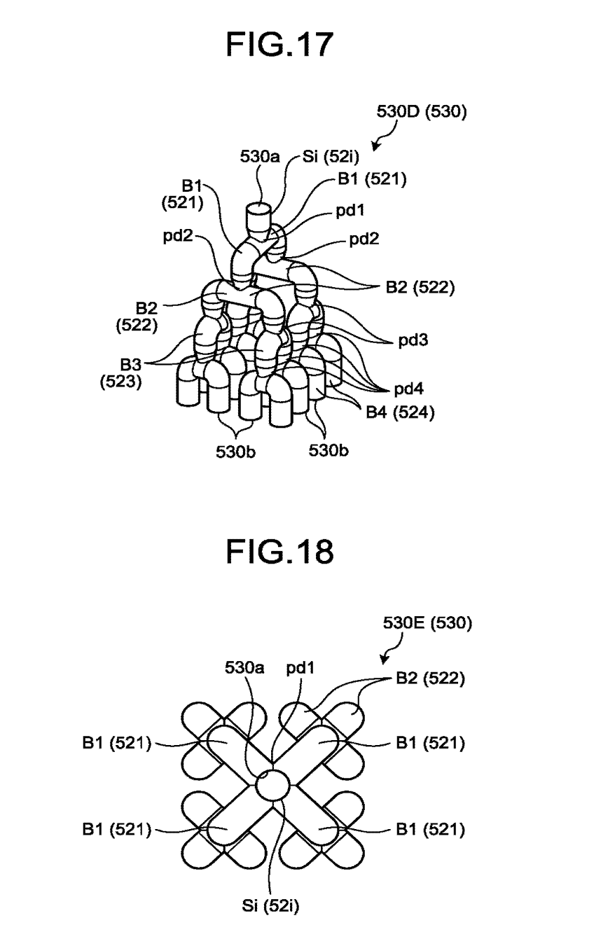

FIG. 15 is a plan view of a discharge-side face 520b of a part of a plate 520D (520) as a branching structure of a third embodiment and the outlets 530b provided in the face 520b. FIG. 16 is a plan view of a virtual stereoscopic image of a path 530D (530) provided in the plate 520D of the third embodiment, and FIG. 17 is a perspective view of the virtual stereoscopic image. FIGS. 16 and 17 stereoscopically show the inner face of the path 530D as a thin tube. In reality, however, the path 530D does not have a tubular form, and the configuration of the plate 520D is not especially limited.

In the present embodiment, in the face 520b, the outlets 530b are arranged on the basis of the tiling of squares as unit shape. That is, the outlets 530b are arranged on the vertexes of the fitted squares, respectively. The example of FIG. 15 corresponds to the arrangement pattern 2 of the outlets 530b.

Further, as illustrated in FIG. 15, a total of sixteen outlets 530b are arranged at the outer periphery of a square area A4 having sides e4 along each which four outlets 530b are aligned in the face 520b of the plate 520D. As illustrated in FIG. 15, the area A4 is divided into four areas Ad4 in each of which four outlets 530b are arranged in a square form.

In view of this, as illustrated in FIGS. 16 and 17, in the path 530D, an introduction path Si diverges into four branches B2 at the first and second diverging points pd1 and pd2 so as to satisfy the conditions 1 to 4, and each branch B2 is connected to four outlets 530b in each area Ad4. Then, each of the four branches B2 diverges into two branches B3 and B4 at the third and fourth diverging points pd3 and pd4 so as to satisfy the conditions 1 to 4 (the numbers of divergences . That is, in the present embodiment, each of the four split branches B2 at the first and second diverging points pd1 and pd2 diverges into 2² (=4) branches B4, and the outlets 530b are provided at the respective downstream ends of the total of sixteen branches B4. The parts forming the branches B1 to B4, of the plate 520D, are branch path parts 521 to 524, respectively.

### Second Modification

A second modification has the same or like configuration as the above embodiments and modification. Thus, the second modification can attain the same or like functions and result (effects) by the same or like configuration.

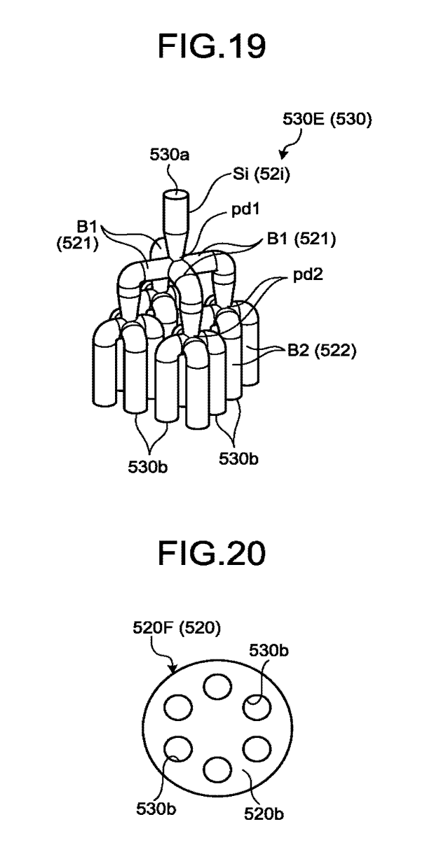

The present modification exemplifies another path 530E in a plate with outlets 530b, which are the same outlets of the plate 520D of the third embodiment illustrated in FIG. 15. FIG. 18 is a plan view of a virtual stereoscopic image of the path 530E (530) provided in the plate of the present modification, and FIG. 19 is a perspective view of the virtual stereoscopic image. FIGS. 18 and 19 stereoscopically show the inner face of the path 530E as a thin tube. In reality, however, the path 530E does not have a tubular form, and the configuration of the plate 520D is not especially limited.

As illustrated in FIGS. 16 and 19, in the path 530E, an introduction path Si diverges into four branches B1 at the first diverging point pd1 so as to satisfy the conditions 1 to 4 (the number of divergences=4), and each of the four branches B1 diverges into four branches B2 at the second diverging point pd2 so as to satisfy the conditions 1 to 4 (the number of divergences=4). That is, in the present modification, the introduction path Si diverges into 4²(=16) branches B2, and the outlets 530b are provided at the respective downstream ends of the total of sixteen branches B2. The parts forming the branches B1 and B2, of the plate 520D, are branch path parts 521 and 522, respectively.

### Fourth Embodiment

A forth embodiment has the same or like configuration as the above embodiments. Thus, the fourth embodiment can attain the same or like functions and result (effects) by the same or like configuration.

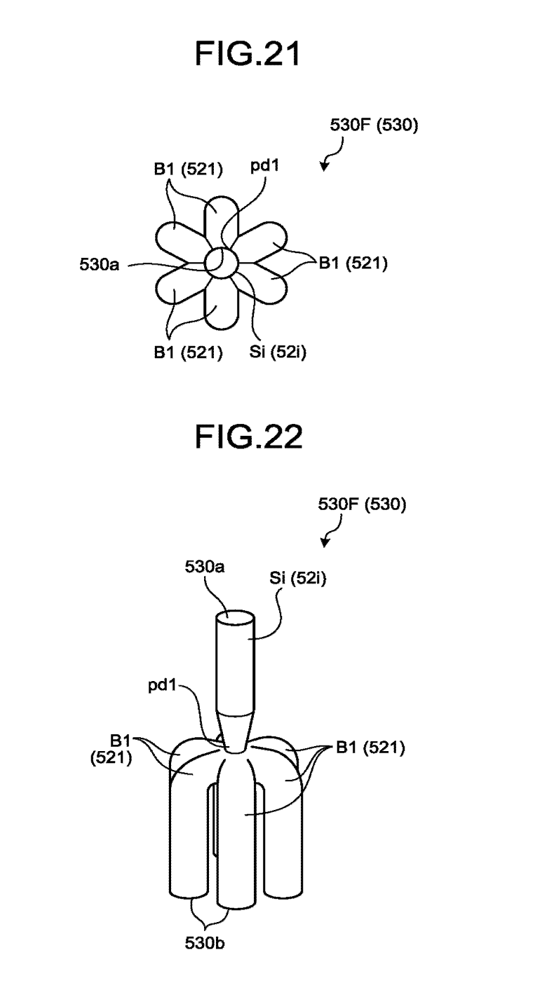

FIG. 20 is a plan view of a discharge-side face 520b of a part of a plate 520F (520) as a branching structure of the fourth embodiment and outlets 530b provided in the face 520b. FIG. 21 is a plan view of a virtual stereoscopic image of a path 530F (530) provided in the plate 520F of the fourth embodiment, and FIG. 22 is a perspective view of the virtual stereoscopic image. FIGS. 21 and 22 stereoscopically show the inner face of the path 530F as a thin tube. In reality, however, the path 530F does not have a tubular form, and the configuration of the plate 520F is not especially limited.

In the present embodiment, in the face 520b, the outlets 530b are arranged on the basis of the tiling of equilateral triangles as unit shape. That is, the outlets 530b are arranged on the vertexes of the fitted regular hexagons, respectively. The example of FIG. 20 corresponds to the arrangement pattern 3 of the outlets 530b.

As illustrated in FIG. 20, a total of six outlets 530b are arranged in the face 520b of the plate 520F. Thus, in the path 530F, an introduction path Si diverges into six branches B1 at the first diverging point pd1 so as to satisfy the conditions 1 to 4 (the number of =6), and the outlets 530b are provided at the respective downstream ends of the six branches B1. The part forming the branches B1, of the plate 520F, is a branch path part 521.

### Third Modification

A third modification has the same or like configuration as the above embodiments and modifications. Thus, the third modification can attain the same or like functions and results (effects) by the same or like configuration.

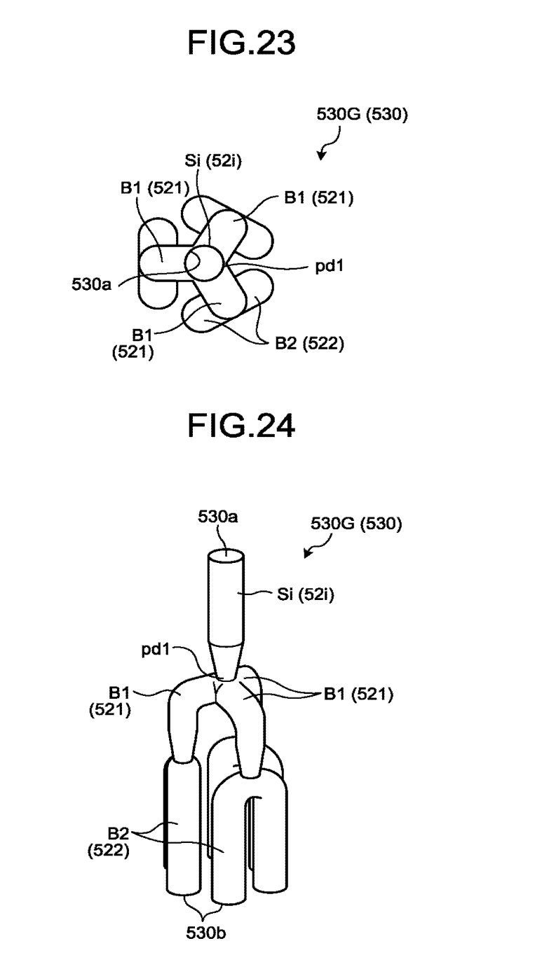

The present modification exemplifies another path 530G in a plate provided with outlets 530b, which are the same outlets of the plate 520F of the third embodiment illustrated in FIG. 20. FIG. 23 is a plan view of a virtual stereoscopic image of the path 530G (530) provided in the plate of the present modification, and FIG. 24 is a perspective view of the virtual stereoscopic image. FIGS. 23 and 24 stereoscopically show the inner face of the path 530G as a thin tube. In reality, however, the path 530G does not have a tubular form, and the configuration of the plate 520F is not especially limited.

As illustrated in FIGS. 23 and 24, in the path 530G, an introduction path Si diverges into three branches B1 at the first diverging point pd1 so as to satisfy the conditions 1 to 4 (the number of divergences=3), and each of the three branches B1 diverges into two branches B2 at the second diverging point pd2 so as to satisfy the conditions 1 to 4 (the number of divergences=2). That is, in the present modification, the introduction path Si diverges into 3×2(=6) branches B2, and the outlets 530b are provided at the respective downstream ends of the total of six branches B2. The parts forming the branches B1 and B2, of the plate 520F, are branch path parts 521 and 522, respectively. Note that if the introduction path Si diverges into two branches at the first diverging point pd1 (the number of divergences=2), and each of the branches B1 diverges into three branches at the second diverging point pd2 (the number of divergences=3), the conditions 2 to 4 cannot be satisfied.

### Fifth Embodiment

A fifth embodiment has the same or like configuration as the above embodiments. Thus, the fifth embodiment can attain the same or like functions and results (effects) by the same or like configuration.

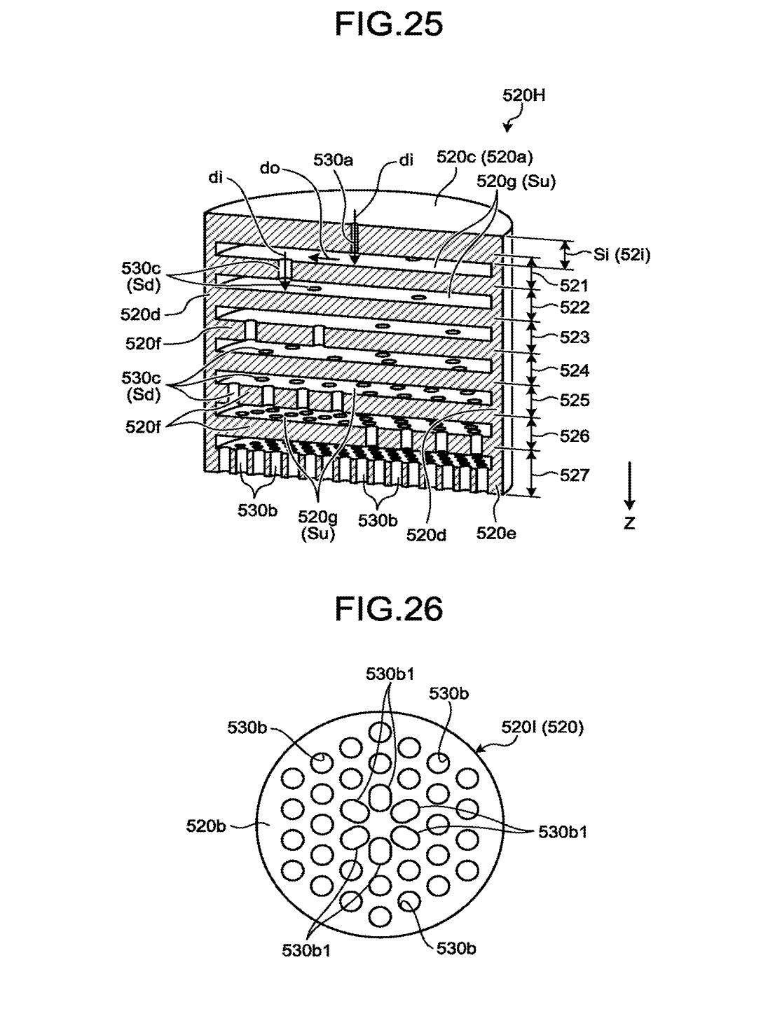

FIG. 25 is a schematic and exemplary perspective view of a cross section of a nozzle 520H having a branching structure of the present embodiment.

As illustrated in FIG. 25, the nozzle 520H has a cylindrical shape and includes a ceiling wall 520c, side walls 520d, a bottom wall 520e, and partition walls 520f. The side walls 520d have a cylindrical shape. The ceiling wall 520c, the partition walls 520f, and the bottom wall 520e are all disc-shaped and substantially equally spaced apart in the axial direction of the side walls 520d. In the nozzle 520H, the ceiling wall 520c and the bottom wall 520e are positioned at axial ends (2 direction) of the nozzle 520H and the side walls 520d. The ceiling wall 520c, the side walls 520d, and the bottom wall 520e extend in a direction intersecting or perpendicular to the axial direction. Chambers 520g are provided, surrounded by two adjacent ones of the ceiling wall 520c, the partition walls 520f, and the bottom wall 520e, and the side walls 520d. The chamber 520g is a flat cylindrical space extending in the direction intersecting or perpendicular to the axial direction. The ceiling wall 520c is provided with an inlet 530a, and the bottom wall 520e is provided with outlets 530b. The outlets 530b are arranged in any of the above arrangement patterns. The partition walls 520f are each provided with cylindrical through holes 530c extending in the axial direction. The through holes 530 connect the chambers 520g on both sides of each partition wall 520f. The closer to the bottom wall 520e the partition walls 520f are, the larger the number of the through holes provided is. The thus-configured nozzle 520H includes, between the introduction port 530a and the outlets 530b, a path in which the chambers 520g and the through holes 530c are alternately arranged in series. The path diverges at the through holes 530c, and the number of the through holes 530c, that is, the number of divergences of the path increases as the path comes closer to the outlets 530b.

The inlet 530a, the outlets 530b, and the through holes 530c linearly extend in parallel to the axial direction direction) of the nozzle 520H and the side walls 520d. There is no overlapping in the inlet 530a and the through holes 530c in the axial direction, and they are offset from each other in the direction perpendicular to the axial direction. Thus, the gas (fluid) flows into the chamber S20g through the inlet 530a and the through holes 530c, flows along the partition wall 520f or in the direction intersecting with the axial direction in the chamber 520g, and then flows out of the chamber 520g through the through holes 530c of the downstream partition wall 520f or the outlets 530b of the bottom wall 520e. Three-dimensional positions of the through holes 530c and the outlets 530b can be set to the positions of the downstream sections Sd of the above embodiments and modifications.

In the nozzle 520H having such a configuration, the inlet 530a exemplifies the introduction path Si, the through holes 530c exemplify the downstream sections Sd, the chambers 520g exemplify the upstream sections Su, the Z direction is an example of the first direction, and the downstream ends of the through holes 530c are an example of diverging points. In each of the branches B, one upstream section Su is shared by multiple downstream sections Sd. The nozzle 520d includes branch path parts 521 to 527 that form the chambers 520g and the through holes 530c.

The present embodiment does not satisfy the conditions 2 to 4 but satisfies the condition 1 and can adopt any of the arrangement patterns 1 to 3 of the outlets 530b. Thus, the present embodiment can attain the effect based on the condition 1 or from the intersecting first and second directions di and od, to be specific, the effect of decreasing a difference in the flow rates in the through holes 530c or the outlets 530b.

### Fourth Modification

A fourth modification has the same or like configuration as the above embodiments and modifications. Thus, the fourth modification can attain the same or like functions and results (effects) by the same or like configuration.

FIG. 26 is a plan view of a discharge-side face 520b of a part of a plate 520I (520) as a branching structure of the fourth modification and outlets 530b provided in the face 520b. As is clear through comparison with FIG. 10, the plate 520I of the present modification is provided with outlets 530b similar to those in the plate 520B of the second embodiment. However, in the present modification, six outlets 530b1 in the center have a long-hole shape extending in a central direction (radial direction), and are larger than the other circular outlets 530b. That is, the plate 520I is provided with the outlets 530b and 530b1 having different opening areas from each other. the present modification, channel resistance (a pressure loss) of the branch connected to the outlets 530b1 is smaller than channel resistance (a pressure loss) of the branch connected to the outlets 530b. This results in a larger flow rate of the gas (fluid) discharged through the outlets 530b1 than that of the gas (fluid) discharged through the outlets 530b. Hence, by differentiating the opening areas of the cutlets 530b and 530b1, the flow rate of the gas (fluid) depending on a location on the face 520b can be changed to obtain appropriate flow rate distribution.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

Further, the configurations and shapes in the embodiments can be partially replaced for implementation. The specification including the configurations and shapes (structure, type, direction, shape, size, length, width, thickness, height, angle, number, layout, position, material, and the like) can be appropriately changed for implementation.

For example, the branching structure and the fluid passage device can be used in devices other than the semiconductor manufacturing device and can also be used alone. Further, the branching structure and the fluid passage device can be applied to liquids, plasma, multi-phase flows, gels, gasses containing powder, solids having fluidity, and the like, in addition to gas. Such substances having fluidity are referred to as fluids The specification of the path can be changed in various manners implementation. For example, the cross section of the channel is not limited to the circular shape. Further, a larger path or branching structure may be configured by combining mutually, in parallel, or in series the paths and branching structures as disclosed above. The path should not be limited to a fluid path, and may be a path for an electrical signal, a high-frequency signal, or an electromagnetic wave. Further, the end face provided with the cutlets may have a curved shape. In this case, for example, the tiling of the regular polygons of FIGS. 3 to 5 is obtained when viewed from one direction, and the end face may be inclined with respect to the plane of the drawings in FIGS. 3 to 5 or may be a curved face.

What is claimed is:

1. A branching structure comprising:
an introduction path part including an introduction path extending in a first direction; and
a plurality of branch path parts each including parallel branch paths, each of the branch paths including an upstream section extending in a second direction intersecting with the first direction and a downstream section extending in the first direction, each of the branch paths continuing into the introduction path or an upstream branch path, the branch path parts including the same number of the upstream sections of the branch paths, and a more downstream one of the branch path parts having a larger number of the downstream sections.

2. The branching structure according to claim 1, wherein
the branch path part includes the upstream sections at a fixed angle interval as viewed from the first direction, and
lengths of the branch paths in each of the branch path parts are substantially the same.

3. The branching structure according to claim 2, comprising
an end face from which outlets downstream of the branch paths are exposed, wherein,
in the end face, the outlets are respectively arranged on vertexes of regular polygons fitted in a plane, as viewed from the first direction.

4. The branching structure according to claim 3, wherein,
in the end face, the outlets are respectively arranged on vertexes of equilateral triangles fitted in a plane, as viewed from the first direction, and
the outlets is are arranged in a hexagonal area having six sides along which four outlets and five outlets are alternately aligned.

5. The branching structure according to claim 3, wherein,
in the end face, the outlets are respectively arranged on vertexes of equilateral triangles fitted in a plane, as viewed from the first direction, and
the outlets are arranged in a regular hexagonal area having six sides except for a center such that four outlets are aligned along each side.

6. The branching structure according to claim 3, wherein,
in the end face, the outlets are respectively arranged on vertexes of equilateral triangles fitted in a plane, as viewed from the first direction, and
the outlets are arranged in a regular hexagonal area having sixsides except for a center such that three outlets are aligned along each side.

7. The branching structure according to claim 3, wherein,
in the end face, the outlets are respectively arranged on vertexes of a regular hexagon, as viewed from the first direction.

8. The branching structure according to claim 3, wherein,
in the end face, the outlets are respectively arranged on vertexes of squares fitted in a plane, as viewed from the first direction, and
the outlets are arranged in a square area having four sides along which four outlets are aligned.

9. The branching structure according to claim 3, wherein the outlets include outlets having different opening areas in the end face.

10. The branching structure according to claim 1, further comprising
a throttle provided in the downstream section, having a gradually decreased cross section area toward a downstream end.
